(19) United States
(12) Patent Application Publication
(10) Pub. No.: US 2018/0164381 A1
(43) Pub. Date: Jun. 14, 2018

(54) MOUNTING SUBSTRATE, AND CURRENT DETECTION DEVICE FOR STORAGE BATTERY

(71) Applicant: NEC Corporation, Tokyo (JP)

(72) Inventor: Katsuya ONOSE, Tokyo (JP)

(73) Assignee: NEC Corporation, Tokyo (JP)

(21) Appl. No.: 15/578,376

(22) PCT Filed: Jun. 1, 2016
(86) PCT No.: PCT/JP2016/002631

§ 371 Date: Nov. 30, 2017

(30) Foreign Application Priority Data
Jun. 4, 2015 (JP) 2015-113737

(51) Int. Cl. G01R 31/36; G01R 19/03; H01M 10/48

(52) U.S. Cl. CPC G01R 31/3658; H01M 10/48; G01R 31/3606; G01R 19/03

(57) ABSTRACT

The purpose of the present invention is to provide a mounting substrate having reduced size and cost, and a current measurement device for a storage battery. In order to achieve the purpose, this mounting substrate is characterized by having: a heat generating element; a temperature sensor for measuring the temperature of the heat generating element; and a slit that surrounds at least a part of the heat generating element and the temperature sensor. Furthermore this current measurement device for a storage battery measures currents flowing in a plurality of cell sense circuits that measure voltages of a plurality of storage batteries, and the sell sense circuits are provided on the mounting substrate that has the heat generating element, the temperature sensor that measures the temperature of the heat generating element, and the slit that surrounds at least the part of the heat generating element and the temperature sensor, the cell sense circuits being provided with a current calculation unit that obtains the currents on the basis of measurement results obtained by the temperature sensor.

### TECHNICAL FIELD

This invention relates to a mounting substrate and a current detection device for a storage battery system.

### BACKGROUND ART

In a storage battery system which is a power source device using a storage battery, a current provided by the storage battery is monitored (e.g. Patent Literature 1). FIG. 10 illustrates a circuit structure of a cell sense line of an existing storage battery system. In the cell sense line connecting each of battery cells (hereinafter, referred to as “cell”) b1 to b4 with a monitoring IC (Integrated Circuit), a current fuse carrying out short circuit protection for each cell, a current detection resistance Rs monitoring a current in the cell, and a current detection circuit are mounted. Outputs of the cells b1 to b4 are connected with output lines to loads in parallel to the cell sense lines. FIG. 10 does not illustrate the output lines.

FIG. 11 illustrates the structure of the current detection circuit in FIG. 10. The current detection circuit detects voltage difference which occurs in a shunt resistance (resistance for current detection) Rs arranged in the cell sense line by using a circuit composed of a plurality of resistances and an operational amplifier. A current calculation unit derives a current value of a current Tout flowing in the cell sense line from the voltage difference Vout which occurs in Rs.

When the number of cells composing an on-board cell module is increased as capacity of an power storage system is increasing in size, the number of current fuses, resistances for current detection and detection circuits are increased and a size and a cost of a monitoring circuit substrate mounting those are increased.

### CITATION LIST

### Patent Literature

### [PTL 1] Japanese Patent Application Laid-Open No. 2003-168488

[PTL 2] Japanese Utility Model Application Laid-Open No. 63-003174 (Japanese Utility Model Application No. 61-96487, specification)

### SUMMARY OF INVENTION

### Technical Problem

When the number of cells composing an on-board cell module is increased, the number of circuits monitoring the cells is increased. The resistance for current detection and the detection circuit are required in order to monitor a current for each cell. If a voltage between the ground and the cell is high, the detection circuit with high withstanding voltage and a voltage divider circuit measuring a high voltage are needed. The size and the cost of the monitoring circuit substrate mounting those are increased.

An objective of the invention is to solve the problem above mentioned and provide a mounting substrate and a current detection device of a storage battery having reduced size and cost.

### Solution to Problem

The invention relates to a mounting substrate including a heat generating element, a temperature sensor for measuring the temperature of the heat generating element, and a slit that surrounds at least a part of the heat generating element and the temperature sensor.

The invention relates to a current detection device for a storage battery that measures currents flowing in a plurality of cell sense circuits that measure voltages of a plurality of storage batteries, wherein the plurality of cell sense circuits are provided on a mounting substrate that has a heat generating element, a temperature sensor that measures the temperature of the heat generating element, and a slit that surrounds at least a part of the heat generating element and the temperature sensor, the cell sense circuit being provided with a current calculation unit that obtains the currents on the basis of measurement results obtained by the temperature sensor.

### Advantageous Effects of Invention

The invention reduces size and cost of the mounting substrate and the current detection device for storage battery.

### BRIEF DESCRIPTION OF DRAWINGS

FIG. 1 a diagram illustrating a layout on a substrate of a pattern element of a first example embodiment of the invention;

FIG. 2 a diagram illustrating temporal change of temperature rise in the pattern element while a current flows;

FIG. 3 a diagram illustrating relation between increased temperature and a current value in the pattern element;

FIG. 4 a block diagram of a circuit for calculating a value of a current flowing in a cell sense line of the first example embodiment;

FIG. 5 a diagram illustrating a layout on a substrate of a thermally isolated area of the first example embodiment of the invention;

FIG. 6 a diagram explaining temperature change and a method for calculating the increased temperature ΔT/t in the pattern element;

FIG. 7 a diagram illustrating an image of a current calculation table of a current calculation unit of the first example embodiment of the invention;

FIG. 8 a diagram illustrating layouts of pattern elements on a substrate of a second example embodiment of the invention, in which (a), (b), (c), and (d) illustrate layouts of a first layer, a second layer, a third layer, and a fourth layer, respectively;

FIG. 9 a cross sectional view of the pattern element of the second example embodiment of the invention, in which (a) and (b) are diagrams illustrating a section A and a section B, respectively;

FIG. 10 a diagram illustrating an existing cell sense line circuit structure;

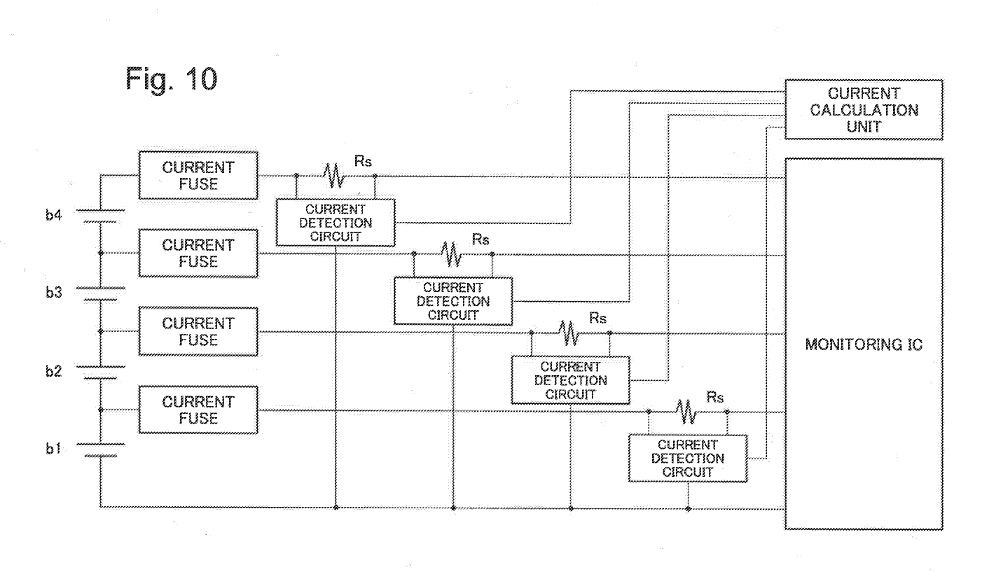

FIG. 11 a diagram illustrating a structure of a current detection circuit of the cell sense line circuit of FIG. 10.

### DESCRIPTION OF EMBODIMENTS

### First Exemplary Embodiment

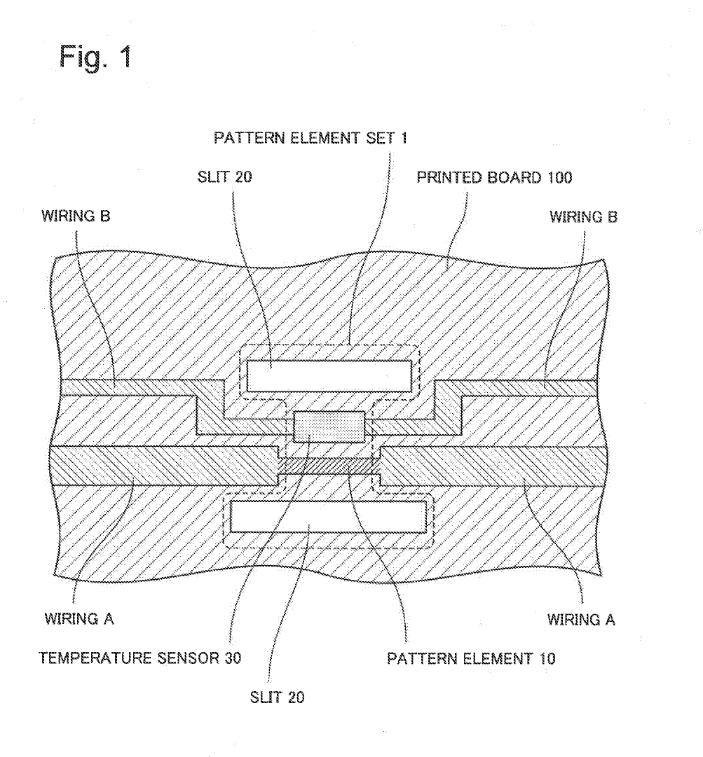

A first example embodiment of the invention is described using FIG. 1 to FIG. 5.

### (Explanation of Structure)

FIG. 1 is a plan view illustrating a layout of a pattern element formed on a mounting substrate of a first example embodiment of the invention. On a printed board 100 on which a cell module monitoring circuit for an power storage system is mounted, a pattern element 10 in which wiring width is partially narrowed is arranged in series in a cell sense line (wiring A) for each cell. In the example embodiment, the pattern element 10 is an existing fuse for protection against short circuit. The pattern element 10 is a common fuse which is used for temperature detection and current value detection on the basis of the temperature.

The pattern element 10 is sandwiched between slits 20. A temperature sensor 30 for detecting a temperature of the pattern element is arranged in an area where the pattern element 10 is located and which is sandwiched between the slits 20. Since the pattern element 10 and the temperature sensor 30 are sandwiched between the slits 20, thermal diffusion is suppressed. The pattern element 10, the slits 20 and the temperature sensor 30 are called a pattern element set 1. Whereas FIG. 1 illustrates one pattern element set 1, the pattern element set 1 is formed for each cell sense line.

The printed board 100 is made of glass epoxy board having thickness of 1.6 mm. The pattern element is made of a copper foil which is 50 um in thickness, 2 mm in length, and 120 um in width, and whose current capacity I (th) is 7 A or more. The wiring A is made of a copper foil which is 50 um in thickness and 500 um in width. The temperature sensor 30 is a NTC (Negative Temperature Coefficient) type thermistor which is NCP18XH103F03RB of MURATA Manufacturing Co. Ltd. The temperature sensor is 1.6 mm in length and 0.8 mm in width.

The slit 20 is formed by boring a through hole in a part of the board using router processing so as to pass through the board. The slit 20 is 2 mm in width and 4.8 mm in length. In this example embodiment, nothing is filled in the slit 20. A heat-insulating material may be filled therein. The two slits 20 surround the pattern element 10 and the temperature sensor 30. Since the two slits 20 surround most of the pattern element 10 and the temperature sensor 30, thermal diffusion is suppressed. The wiring A in which the pattern element 10 is arranged is a part of the cell sense line. A wiring B connects the temperature sensor 30 with a current calculation unit described below. The pattern element set 1 composed of the pattern element 10, the slits 20, and the temperature sensor 30 is arranged in the cell sense line for each cell.

The temperature sensor 30 for measuring a temperature of each pattern element is connected with the current calculation unit. A temperature sensor 80 for measuring a temperature of the printed board 100 is connected with the temperature calculation unit. The temperature calculation unit has a function of calculating an increased temperature in the pattern element on the basis of a temperature of the pattern element and a temperature of the board, and a function of calculating an increased temperature per unit time in the pattern element. The temperature calculation unit further includes a table by which a value of a current flowing in the pattern element is determined on the basis of the board temperature, the increased temperature in the pattern element, and the increased temperature per unit time in the pattern element.

### (Explanation of Operation)

In the example embodiment, a wiring width of a part of the cell sense line is narrowed. The narrowed part of the pattern element 10 has high resistance and promotes heat generation (joule heat) while a current flows in the narrow part.

In the pattern element 10 of the example embodiment, a wiring pattern width, a thickness, a length, and conductivity are set so that current capacity takes a predetermined value I (th). If a current which exceeds I (th) flows in the pattern element 10, the pattern element 10 is fused.

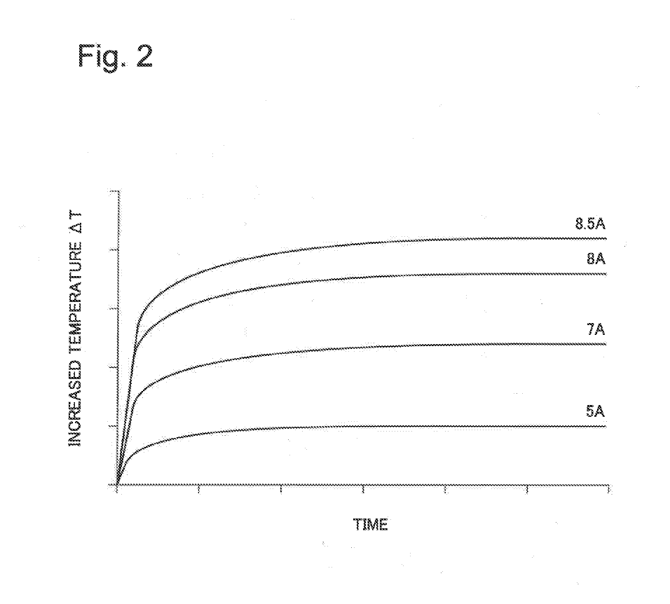

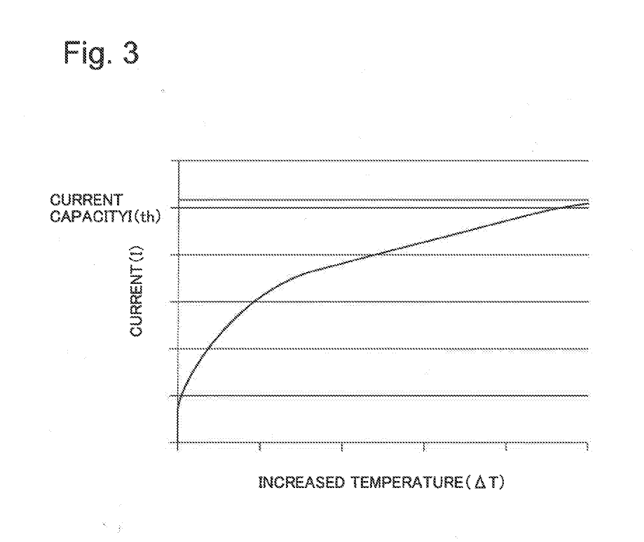

If a current of I (th) or less flows in the pattern element 10, heat (joule heat) generation with W=I²×R occurs due to the wiring resistance R of the pattern element 10 and the temperature of the pattern element 10 rises in proportion to power consumption W. The increased temperature ΔT is proportional to the square of the value of the current flowing in the pattern element 10 compared with a temperature before the current flows. When flow of a constant current continues, an amount of generated heat in the pattern element 10 corresponds to an amount of diffused heat therefrom, and a thermally balanced state corresponding to the current value is generated as shown in FIG. 2 if an external temperature, e.g. the board temperature does not change. In the pattern element 10 in the thermally balanced state, increased temperature/current characteristics as shown in FIG. 3 is obtained.

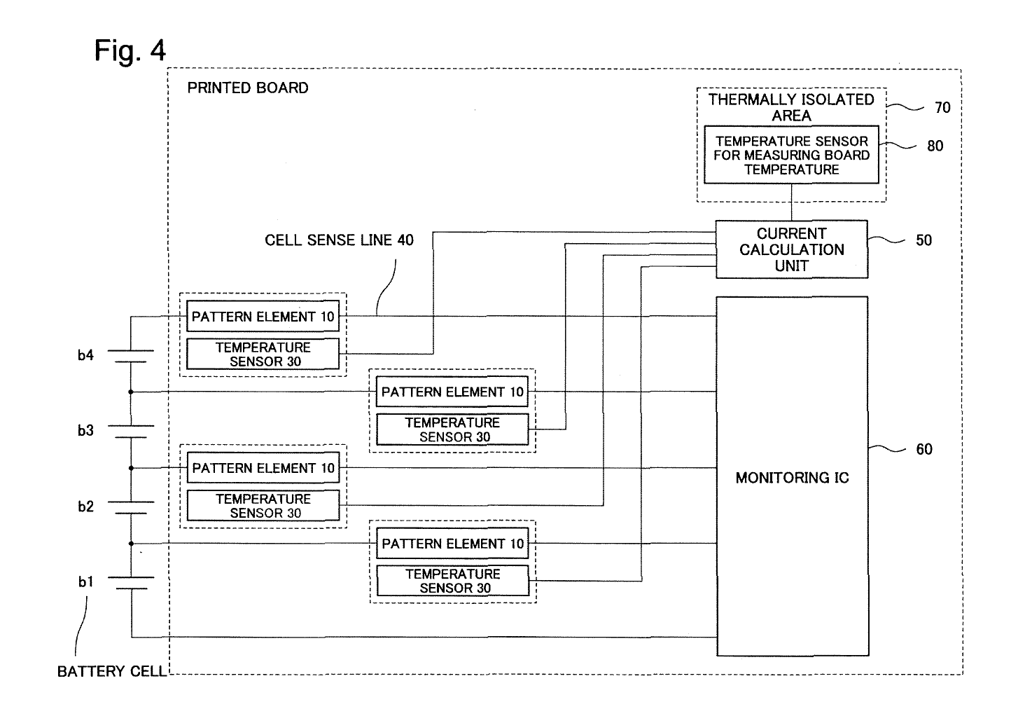

FIG. 4 illustrates a block diagram of a circuit for calculating a value of current flowing in each cell sense line 40. The cell sense lines 40 which are connected with cells, the pattern element set 1 (slit 20 is omitted), a current calculation unit 50, a monitoring IC 60, a thermally isolated area 70, and a temperature sensor for measuring a board temperature 80 are arranged on the printed board 100. These components compose a battery module monitoring circuit for a power storage system. Outputs of the cells b1 to b4 are connected with output lines to loads in parallel to the sell sense lines. The output lines are omitted in FIG. 4.

Output of the temperature sensor 30 in each pattern element set 1 which is formed in the sell sense line 40 of each of the cells b1 to b4 enters the current calculation unit 50. The monitoring IC 60 is connected with each cell sense line 40 and monitors an operation of each of the cells b1 to b4.

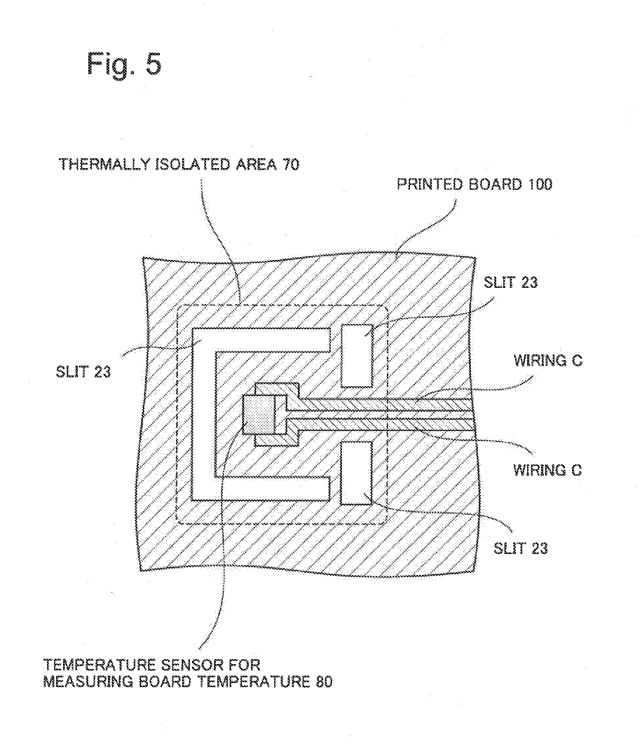

The current calculation unit 50 is connected with the temperature sensor for measuring a board temperature 80 which is located in the thermally isolated area 70 which is thermally isolated from surroundings in the printed board 100. FIG. 5 illustrates a layout of the thermally isolated area 70 where the temperature sensor for measuring a board temperature 80 is located. Slits 23 form the thermally isolated area 70 where influence of temperature change of external components is suppressed in an area of the board 100 on which a component is not mounted. The temperature sensor for measuring a board temperature 80 is located on the area 70. The slits 23 surround most of surroundings of the temperature sensor for measuring a board temperature 80. A wiring C is arranged in order to send outputs of the temperature sensor for measuring a board temperature 80 to the current calculation unit 50. The slits 23 may be formed by the method of forming the slit 20 in the pattern element set 1.

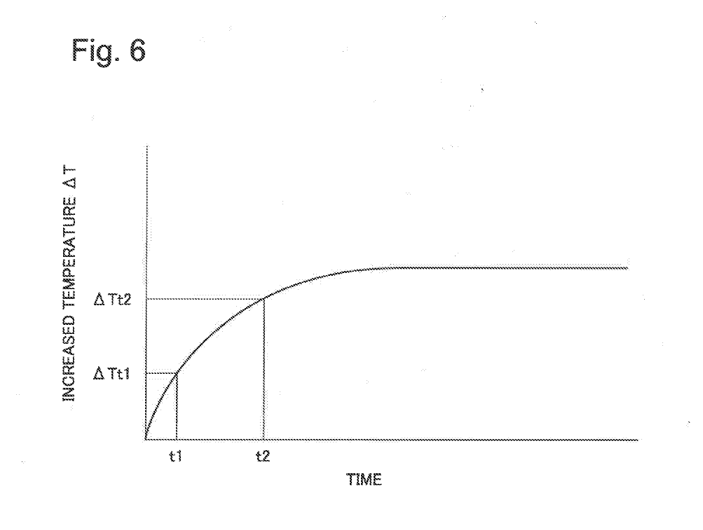

A method by which the current calculation unit 60 calculates a current flowing in one pattern element 10 is explained below. FIG. 6 illustrates a temperature of the pattern element and a calculation image of the increased temperature ΔT/t per unit time. The current calculation unit subtracts the temperature detected by the temperature sensor for measuring a board temperature from the detected temperature of the pattern element and calculates the increased temperature ΔT/t of the pattern element. The increased temperature ΔT/t per unit time is calculated using the following formula:

ΔT/t=(ΔTt2−ΔTt1)/(t2−t1)

where ΔTt1 is an increased temperature obtained at time t1, and ΔTt2 is an increased temperature obtained at time t2.
When the increased temperature ΔT/t per unit time is calculated, the measurement interval t2−t1 is always set to a predetermined value.

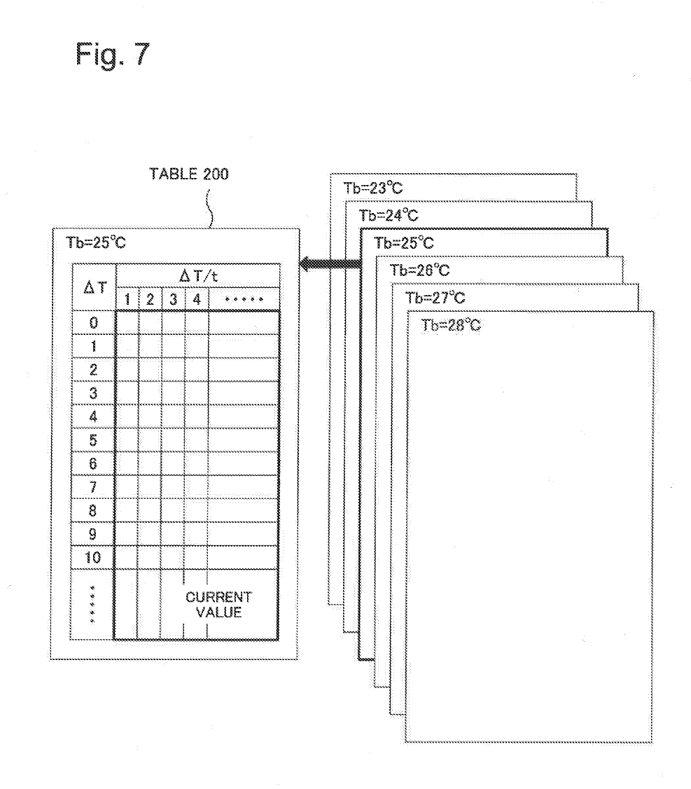

FIG. 7 illustrates an image of a current calculation table of the current calculation unit 60. The current calculation unit 60 has a table 200 by which a current value is calculated from ΔT and ΔT/t for each board temperature measured by the temperature sensor for measuring a board temperature. Resistance of a conductor forming the pattern element 10 has a temperature characteristic. Holding the table 200 for each board temperature (at intervals of 1° C. in FIG. 7), the current calculation unit 60 copes with the temperature characteristic of the wiring resistance of the pattern element 10. When the board temperature Tb is 25° C., the current calculation unit 60 determines, by using the temperature table of Tb=25° C., a current value in the cell sense line 40 in which the pattern element 10 is arranged on the basis of the increased temperature ΔT of the pattern element 10 and the increased temperature per unit time ΔT/t. Even though the increased temperatures ΔT for a certain unit time are the same, a value of the current flowing in the cell sense line 40 varies depending on how the temperature of ΔT is increasing (whether the temperature is saturated or increasing). When T=1 and t=1 is given, for example, ΔT/t is not established, but ΔT/t=(ΔTt2−ΔTt1)/1 is established. The table 200 is prepared every one degree in advance. The table 200 is stored in the current calculation unit 60. The temperature of the pattern element 10 is higher than a temperature of the surrounding area. Therefore a part of the joule heat generated in the pattern element 10 is conducted to the wiring A. Since the slits 20 does not make perfect thermal isolation of the pattern element 10 from the surrounding area, a part of the joule heat is conducted to the printed board 100. The table 200 which is a temperature/current characteristic is determined on the basis of a balance between the heat conduction and the joule heat generation. The table 200 incorporates influence of the heat conduction above described.

Current detection is carried out for each pattern element set 1, and current detection is carried out for each cell sense line 40. A state of the cell sense line 40 is confirmed by a detected value in the current detection. If an abnormal current is detected, an alarm LED (Light Emission Diode) in the power storage system is turned on, an alarm sound is generated, or the power storage system stops in order to safely operate the power storage system.

If a current which exceeds I (th) flows in the pattern element 10, the pattern element 10 is fused (open mode). The fusion cutting prevents the excess current from flowing in the cell sense line 40 of the following cells.

### (Explanation of Effect)

In the example embodiment, the pattern element and the temperature sensor are thermally isolated from the surroundings on the board. The pattern element is therefore hard to be affected by temperature change in external components. The temperature of the pattern element is a temperature in which an increased temperature due to current flowing is added to the board temperature. It becomes possible to calculate the increased temperature due to current flowing from the temperature of the pattern element and the board temperature and carry out current detection.

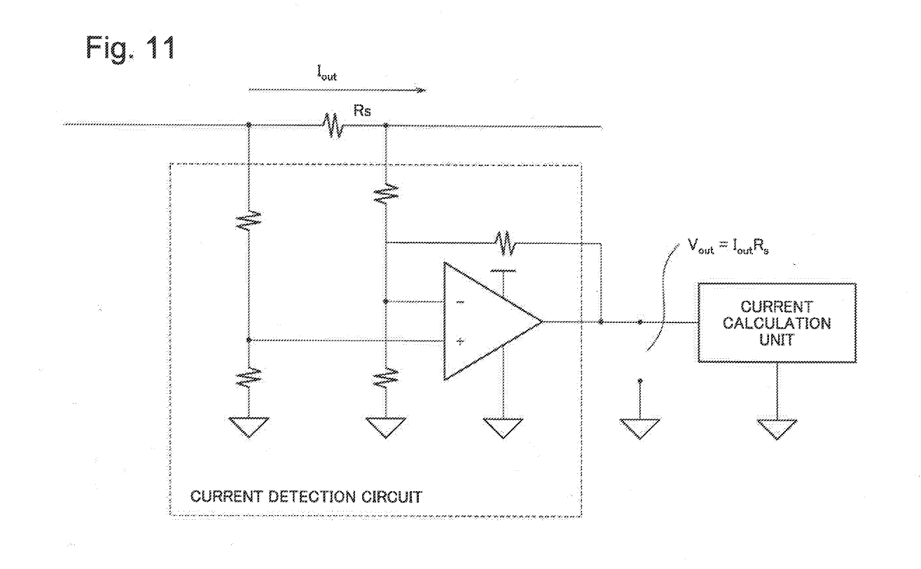

In the example embodiment, mounting of a component corresponding to a shunt resistance for current detection is omitted by using short circuit protection area using the pattern element in order to detect a current. Further since a current value is calculated by using a detected temperature, the detection circuit including a plurality of resistances and an amplifier shown in FIG. 11 can be replaced by one temperature sensor. Safe current detection in which an isolation state from a measurement line is maintained is carried out without a circuit for detecting a current in a high voltage band and a high-priced current detection IC handling a high voltage. According to the example embodiment, current detection and short circuit protection for a power storage system can be achieved by the reduced and low cost device.

Patent Literature 2 describes the printed board having a pattern fuse made of a copper foil area. The printed board has a heat-insulating part along the shape of the pattern fuse. The heat-insulating part is a slit or a through hole which is formed in the board. The example embodiment of the Patent Literature includes the following descriptions. The slit and the through hole, or the slit is formed on both sides of the copper foil area. Heat is not conducted from the copper foil area to the printed board even though a current which slightly exceeds the rated current flows in the copper foil area. Therefore fusion occurs in a short time and the printed board is not burned.

In Patent Literature 2, slits are formed on the both sides of the copper foil area with narrow width which is a fuse. An objective of the slits is not to insulate heat for temperature measurement, but to insulate heat at the time of fusion of the fuse.

### Second Example Embodiment

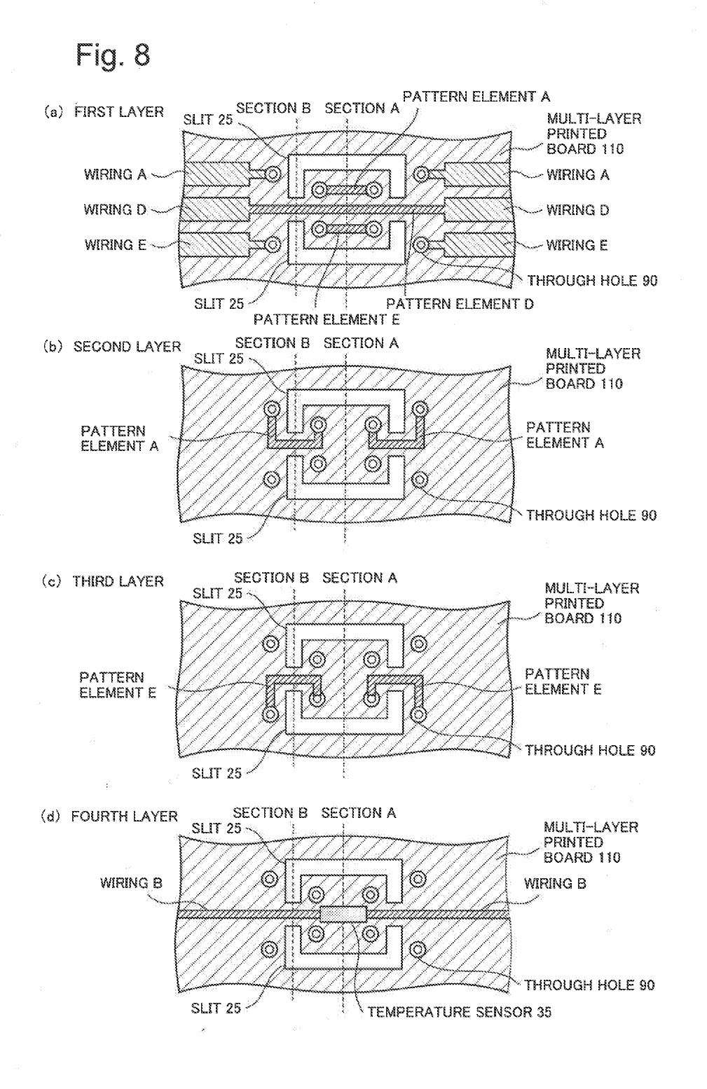

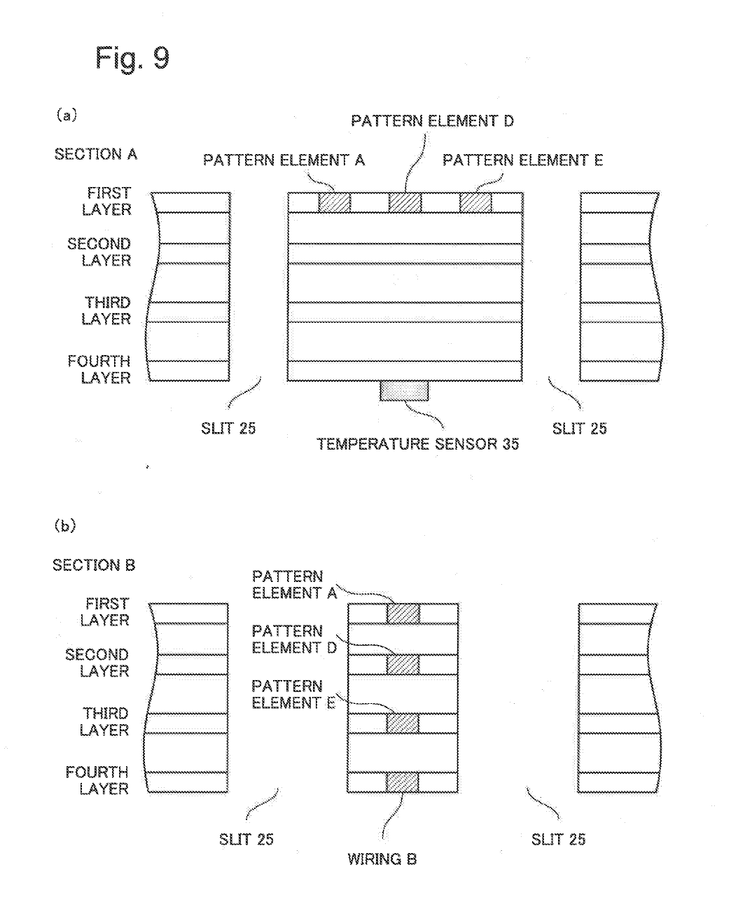

A second example embodiment of the invention is described below. FIG. 8 (a) to FIG. 8 (d) illustrate layouts of the pattern elements A, D, E on a multi-layer printed board 110 (hereinafter, referred to as “multi-layer board”) of the example embodiment. FIGS. 9 (a), (b) illustrate a cross sectional view of the multi-layer board including the pattern elements A, D, E.

A pattern elements in which a wiring width is partially narrowed is arranged in each cell sense line in series on the multi-layer board on which a cell module monitoring circuit for a power storage system is mounted, like the first example embodiment. In the example embodiment, a plurality of pattern elements 10 are adjacent to each other. The pattern elements are called a group of adjacent pattern elements. A slits 25 which pass through the multi-layer board are located in most of the surrounding area of the group of adjacent pattern elements. On the back of the multi-layer board of the area in which each group of adjacent pattern elements is located, one temperature sensor 35 for measuring the temperature of the group of adjacent pattern elements is arranged.

The temperature sensor 35 for measuring the temperature of the group of adjacent pattern elements is connected with the current calculation unit. A temperature sensor for measuring a temperature of the printed board is connected to the current calculation unit, like the first example embodiment. The current calculation unit includes a function of calculating an increased temperature of the group of adjacent pattern elements by using the temperature of the group of adjacent pattern elements and the board temperature and a function of calculating an increased temperature per unit time in the adjacent pattern elements. The current calculation unit has a table by which a value of a current flowing in the group of the adjacent pattern elements is determined on the basis of the board temperature, the increased temperature in the group of adjacent pattern elements, and the increased temperature per unit time in the group of adjacent pattern elements.

The multi-layer board 110 of the example embodiment is a four-layer board. On the multi-layer board 110, the adjacent pattern elements A, D, and E which are arranged in the wiring A, D, and E, respectively, are located. Each of the wiring A, D, and E is a part of different cell sense line. The slits 25 surround the three pattern elements on the both sides thereof. In order to further suppress thermal diffusion through the slits, the three pattern elements are arranged on a first layer, which is a surface layer, and the temperature sensor 35 and the wiring B, which connects the temperature sensor 35 with the current calculation unit, are arranged on a fourth layer which is a surface layer of the back of the multi-layer board. Both ends of each of the three pattern elements are allocated to the first layer, a second layer and third layer which are inner layers, by using a through hole 90, and the both ends of each of the three pattern elements and the wiring B are overlapped in the direction of thickness of the board as shown in the section B of FIG. 9. Therefore an area which is surrounded by the slits is reduced. All the pattern element A, D, and E are exposed to an outside on the surface layer (first layer). When a current which exceeds I (th) flows in any one of the pattern elements, the pattern element is fused.

This example embodiment is similar to the first example embodiment except the layout of the pattern elements on the multi-layer board 110 and one temperature sensor for detecting temperature change in the three pattern elements A, D, and E. Thereby it becomes possible to detect and monitor current change in a plurality of pattern elements all together. This example embodiment includes a plurality of monitoring ICs, and can be applied to an objective of monitoring a plurality of cell sense lines by one monitoring IC and detecting abnormality of the cell sense line for each monitoring IC. It becomes possible to achieve current detection and short circuit protection by a narrow area of the pattern element and few temperature sensors.

### Other Example Embodiments

In the first and second example embodiments, the short circuit protection area employing the pattern element is used for current detection. It is possible that the pattern element is made by narrowing a wiring width of the cell sense line in addition to the fuse in the short circuit protection area, the temperature sensor is arranged adjacent to the pattern element, the slits surrounds the pattern element and the temperature sensor, and temperature increase is measured by sending a current through the pattern element. In this case, since the pattern element is not used for short circuit protection, the pattern element is not reduced in size compared with the pattern element carrying out short circuit protection. In this example embodiment, the detection circuit shown in FIG. 11 is replaced with one temperature sensor to be reduced in size, and safe current detection is carried out while maintaining insulation state from a measurement line without adding a circuit performing current detection in a high voltage band and without adding a high priced current detection IC handling a high voltage.

In the above example embodiment, the board temperature is measured using the temperature sensor for measuring the board temperature 80. If a board temperature before operation of a storage battery system is nearly the same as the temperature in the surroundings of the system, e.g. the temperature of an area where the system is located, the temperature sensor for measuring a board temperature 80 and the thermally isolated area 70 may be omitted and a current value may be calculated by considering the temperature of in surroundings to the board temperature.

In the above example embodiment, the pattern element is arranged in the cell sense line (between cell and monitoring IC). The pattern element may be arranged in a power source line between the cell and a load.

In the first and second example embodiments, the pattern element in which the width of wiring is narrower than the width of the other wiring part is used. The pattern element which generates larger amount of heat than heat generated by the other wiring part may be formed by thinning the thickness of wiring or by using a member with low conductivity.

### INDUSTRIAL APPLICABILITY

The invention is applied to a power storage system having many battery cells connected to each other in series and a monitoring function for each cell, in particular which requires a small size and low cost.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

This application is based upon and claims the benefit of priority from Japanese Patent Application No. 2015-113737, filed on Jun. 4, 2015, the disclosure of which is incorporated herein in its entirety by reference.

### REFERENCE SIGNS LIST

1 pattern element set
10 pattern element
20, 23, 25 slit
30, 35 temperature sensor
40 cell sense line
50 current calculation unit
60 monitoring IC
70 thermally isolated area
80 temperature sensor for measuring board temperature
90 through hole
100 printed board
110 multi-layer board
200 table

1. A mounting substrate, comprising:
a heat generating element;
a temperature sensor that measures the temperature of the heat generating element; and
a slit that surrounds at least a part of the heat generating element and the temperature sensor.

2. The mounting substrate of claim 1, wherein the plurality of heat generating elements are arranged adjacent to each other, the temperature sensor is located adjacent to the plurality of heat generating elements, and the slit surrounds at least a part of the plurality of heat generating elements and the temperature sensor.

3. The mounting substrate of claim 1, further comprising: an element for short circuit protection that is used as the heat generating element.

4. The mounting substrate of claim 3, wherein the heat generating element is an area whose width is narrowed to increase a resistance thereof.

5. A current detection device for storage battery that measures currents flowing in a plurality of cell sense circuits that measure voltages of a plurality of storage batteries, wherein
the plurality of cell sense circuits are provided on a mounting substrate that has a heat generating element, a temperature sensor that measures the temperature of the heat generating element, and a slit that surrounds at least a part of the heat generating element and the temperature sensor, and
the current detection device comprises a current calculation unit that obtains the currents on the basis of measurement results obtained by the temperature sensor.

6. The current detection device for storage battery of claim 5, wherein the mounting substrate has a thermally isolated area and a temperature sensor that measures the temperature of the substrate, and the current calculation unit obtains the currents by calculating an increased temperature in the heat generating element on the basis of difference between measurement results obtained by the temperature sensor and measurement results obtained by the temperature sensor that measures the temperature of the substrate.

7. The current detection device for storage battery of claim 5, wherein, the mounting substrate is a multi-layer substrate, the heat generating element is arranged on one layer of the two surface layers of the multi-layer substrate, and the temperature sensor is arranged on the other layer of the two surface layers.

8. The current detection device for storage battery of claim 5, wherein the current calculation unit includes a current value table that determines the current on the basis of the increased temperature for a predetermined time in the heat generating element caused by a current flowing in the heat generating element.

9. The current detection device for storage battery of claim 8, wherein the current value table is stored for each temperature of the substrate.
